(19) United States
(12) Patent Application Publication
(10) Pub. No.: US 2026/0026306 A1
(43) Pub. Date: Jan. 22, 2026

(54) DONOR

(71) Applicant: LG DISPLAY CO., LTD., SEOUL (KR)

(72) Inventor: Suhun LEE, Gyeonggi-do (KR)

(21) Appl. No.: 19/091,947

(22) Filed: Mar. 27, 2025

(30) Foreign Application Priority Data
Jul. 16, 2024 (KR) 10-2024-0093844

(51) Int. Cl. H01L 21/683; H10H 29/03

(52) U.S. Cl. CPC H01L 21/6835; H10H 29/03

(57) ABSTRACT

A donor includes: a substrate; a resin layer disposed on the substrate and including a base portion and a plurality of protrusions; and a glass layer disposed between the plurality of protrusions on the resin layer.

### CROSS-REFERENCE TO RELATED APPLICATIONS

This application claims the priority of Korean Patent Application No. 10-2024-0093844 filed on Jul. 16, 2024, in the Korean Intellectual Property Office, the disclosure of which is incorporated herein by reference in its entirety.

### TECHNICAL FIELD

The present disclosure relates to a donor for transferring a light-emitting element, and more specifically, to a donor capable of improving the transfer precision of a light-emitting element.

### BACKGROUND

As display devices which are used for a monitor of a computer, a television, a cellular phone, or the like, there are an organic light emitting display (OLED) device which is a self-emitting device and a liquid crystal display (LCD) device which requires a separate light source. An applicable range of the display device is diversified to personal mobile devices as well as monitors of computers and televisions and a display device with a large display area and a reduced volume and weight is being studied.

In addition, recently, a display device including a light-emitting diode (LED) have been attracting attention as next generation display devices. Since the LED is made of an inorganic material rather than an organic material, reliability is excellent so that a lifespan thereof is longer than that of the liquid crystal display device or the organic light emitting display device. In addition, the LED has a fast-lighting speed, excellent luminous efficiency, and a strong impact resistance so that a stability is excellent and an image having a high luminance may be displayed. The display device including the LED may be manufactured by transferring the LED using a donor.

### SUMMARY

An object of the present disclosure is to provide a donor that improves transfer precision of a light-emitting element.

Another object of the present disclosure is to provide a donor that can optimize the process and reduce production energy by minimizing a transfer defect of an unselected light-emitting element during a transfer process.

Objects of the present disclosure are not limited to the above-mentioned objects, and other objects, which are not mentioned above, can be clearly understood by those skilled in the art from the following descriptions.

A donor according to one implementation of the present disclosure includes: a substrate; a resin layer disposed on the substrate and including a base portion and a plurality of protrusions; and a glass layer disposed between the plurality of protrusions on the resin layer.

A donor according to one implementation of the present disclosure includes: a substrate made of a material having rigidity; a resin layer disposed on the substrate and including a base portion and a plurality of protrusions; and a rigid layer disposed on the resin layer and having a plurality of holes disposed to accommodate the plurality of protrusions.

Other detailed matters of the example implementations are included in the detailed description and the drawings.

The present disclosure can improve the transfer precision of the donor by minimizing the transfer of light-emitting elements other than a target area to the donor in a transfer process of a plurality of light-emitting elements using a donor.

The present disclosure can optimize the transfer process by minimizing defects due to transfer of unselected light-emitting elements to a donor.

The effects according to the present disclosure are not limited to those described above, and other various effects can be achieved from implementations described in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of a donor according to one implementation of the present disclosure.

FIG. 2A is a cross-sectional view of the donor according to one implementation of the present disclosure.

FIG. 2B is a cross-sectional view illustrating a state in which the donor and a temporary substrate are aligned according to one implementation of the present disclosure.

FIGS. 3A to 3F are cross-sectional views illustrating a manufacturing process of the donor according to one implementation of the present disclosure.

FIG. 4A is a plan view illustrating a temporary substrate used in a transfer process of a light-emitting element using the donor according to one implementation of the disclosure.

FIG. 4B is a plan view illustrating a state in which a light-emitting element is transferred to a target substrate using the donor according to one implementation of the present disclosure.

FIGS. 5A to 5F are process diagrams for explaining a method for transferring the light-emitting element using the donor according to one implementation of the present disclosure.

FIG. 6 is a cross-sectional view exemplarily illustrating various target substrates onto which the light-emitting element can be transferred using the donor according to one implementation of the present disclosure.

FIG. 7A is a cross-sectional view of a donor according to another implementation of the present disclosure.

FIG. 7B is a cross-sectional view illustrating a state in which the donor and a temporary substrate are aligned according to another implementation of the present disclosure.

FIGS. 8A to 8D are cross-sectional views illustrating a manufacturing process of the donor according to another implementation of the present disclosure.

FIG. 9A is a cross-sectional view of a donor according to still another implementation of the present disclosure.

FIG. 9B is a cross-sectional view illustrating a state in which the donor and a temporary substrate are aligned according to still another implementation of the present disclosure.

FIGS. 10A to 10E are cross-sectional views illustrating a manufacturing process of the donor according to still another implementation of the present disclosure.

FIG. 11A is a cross-sectional view of a donor according to still another implementation of the present disclosure.

FIG. 11B is a cross-sectional view illustrating a state in which the donor and a temporary substrate are aligned according to still another implementation of the present disclosure.

FIGS. 12A to 12E are cross-sectional views illustrating a manufacturing process of a donor according to still another implementation of the present disclosure.

FIG. 13A is a cross-sectional view of a donor according to still another implementation of the present disclosure.

FIG. 13B is a cross-sectional view illustrating a state in which the donor and a temporary substrate are aligned according to still another implementation of the present disclosure.

### DETAILED DESCRIPTION

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various implementations of the present disclosure can be partially or entirely adhered to or combined with each other and can be interlocked and operated in technically various ways, and the implementations can be carried out independently of or in association with each other.

Hereinafter, various implementations of the present disclosure will be described in detail with reference to accompanying drawings.

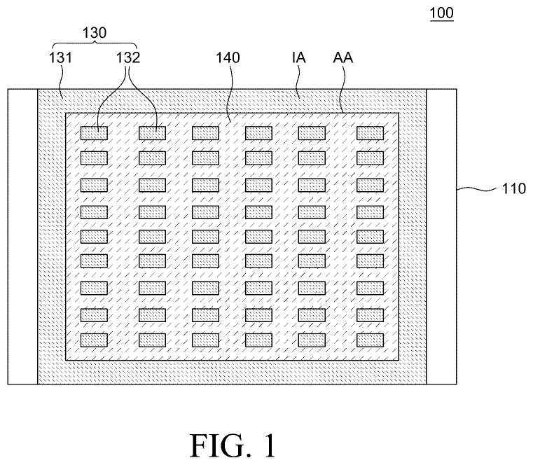

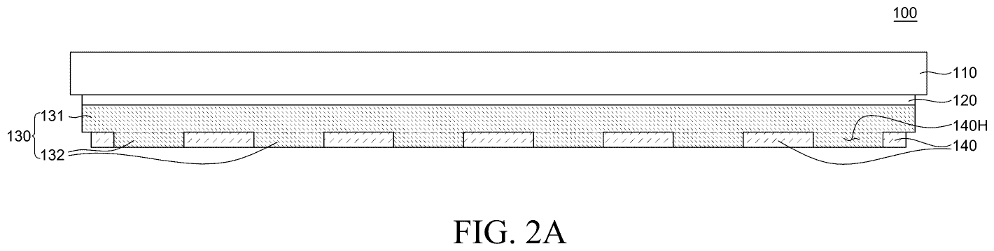

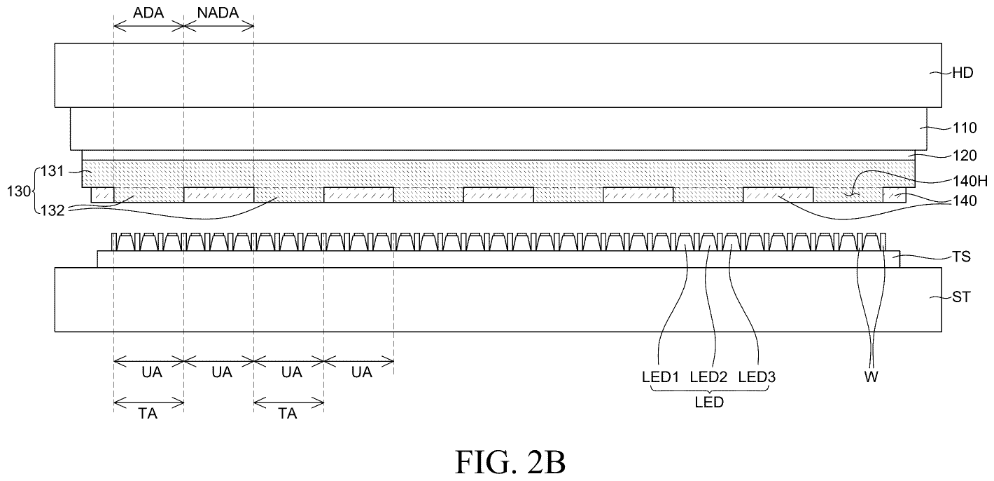

FIG. 1 is a plan view of a donor according to one implementation of the present disclosure. FIG. 2A is a cross-sectional view of the donor according to one implementation of the present disclosure. FIG. 2B is a cross-sectional view illustrating a state in which the donor and a temporary substrate are aligned according to one implementation of the present disclosure.

Referring to FIGS. 1 to 2B, a donor 100 is a member for transferring a plurality of light-emitting elements LED to a target substrate. The donor 100 can transfer the plurality of light-emitting elements LED disposed on a wafer or a temporary substrate TS to a target substrate, such as a substrate of a display device. For example, the donor 100 can be bonded to the wafer or the temporary substrate TS on which the plurality of light-emitting elements LED are disposed, so that the plurality of light-emitting elements LED can be transferred to the donor 100. In addition, the donor 100 to which the plurality of light-emitting elements LED are temporarily attached can be bonded to the target substrate, so that the plurality of light-emitting elements LED can be transferred to the target substrate. Accordingly, by transferring the plurality of light-emitting elements LED from the temporary substrate TS to the target substrate using the donor 100, an electronic product, such as a display device, can be formed.

In this case, the light-emitting element LED can be a light-emitting diode (LED) or a micro light-emitting diode (Mirco LED).

The donor 100 includes a substrate 110, an adhesive layer 120, a resin layer 130, and a glass layer 140.

The substrate 110 is a structure for supporting various components included in the donor 100. The substrate 110 can be made of a material that is at least harder than the resin layer 130 in order to minimize warping of the resin layer 130. The substrate 110 can support the resin layer 130 which has relatively softer properties than the substrate 110, thereby minimizing deformation thereof during the transfer process. The substrate 110 can be formed with the thickest thickness among the components of the donor 100 and can support the remaining components of the donor 100. For example, the substrate 110 can be formed with a thickness of about 500 μm. In addition, the substrate 110 can be made of a material that is rigid and transparent. For example, the substrate 110 can be made of a plastic material such as glass, poly carbonate (PC), or poly ethylene terephthalate (PET), but is not limited thereto.

The adhesive layer 120 is disposed on the substrate 110. The adhesive layer 120 adheres the substrate 110 and the resin layer 130 to each other. The adhesive layer 120 can be made of a material having adhesive properties, and can be made of, for example, an optical clear adhesive (OCA), a pressure sensitive adhesive (PSA), or the like, but is not limited thereto.

The resin layer 130 is disposed on the adhesive layer 120. The resin layer 130 can support a plurality of protrusions 132 to which the plurality of light-emitting elements LED are attached during the transfer process. The resin layer 130 can be made of a polymer resin having viscoelasticity and adhesiveness, and for example, the resin layer 130 can be made of, but is not limited to, poly di methyl siloxane (PDMS), poly urethane acrylate (PUA), poly ethylene glycol (PEG), poly methyl meth acrylate (PMMA), poly styrene (PS), epoxy resin, urethane resin, acrylic resin, or the like, but is not limited thereto.

The resin layer 130 includes an active area AA and an inactive area IA. The active area AA can be an area where the plurality of protrusions 132 to which the plurality of light-emitting elements LED are attached are disposed, and can be disposed to correspond to the wafer, the temporary substrate TS, or the target substrate during the transfer process.

The inactive area IA is disposed to surround the active area AA. Configurations for stably performing the transfer process of the donor 100 can be disposed in the inactive area IA. For example, a plurality of dummy protrusions can be disposed in the inactive area IA to stably fix the donor 100 when the donor 100 is bonded to another configuration, but the present disclosure is not limited thereto.

The resin layer 130 includes a base portion 131 and the plurality of protrusions 132.

The base portion 131 is disposed in both the inactive area IA and the active area AA of the resin layer 130. The base portion 131 is a portion that supports the components of the resin layer 130 and can have a flat shape, but is not limited thereto.

The plurality of protrusions 132 are disposed on the base portion 131 in the active area AA. Referring to FIG. 1, the plurality of protrusions 132 can be disposed, for example, in a matrix shape on the base portion 131. The plurality of protrusions 132 can be formed by extending from one surface of the base portion 131 as protrusions to which the plurality of light-emitting elements LED are temporarily attached during the transfer process. The plurality of protrusions 132 can be formed integrally with the base portion 131 and can be formed of a polymer material having viscoelasticity and adhesiveness similar to that of the base portion 131.

The glass layer 140 is disposed on the resin layer 130. The glass layer 140 is disposed between the plurality of protrusions 132 on the resin layer 130. The glass layer 140 can be disposed so as to fill all portions between the plurality of protrusions 132 on the base portion 131.

A plurality of holes 140H are disposed in the glass layer 140. Accordingly, the glass layer 140 can have a mesh shape including a plurality of holes. The plurality of protrusions 132 can be accommodated in the plurality of holes 140H of the glass layer 140. In addition, the glass layer 140 can be disposed to be in contact with the base portion 131 between the plurality of protrusions 132.

Referring to FIGS. 2A and 2B, the surface of the glass layer 140 can be disposed on the same plane as the tips of the plurality of protrusions 132. That is, the thicknesses of the plurality of protrusions 132 and the glass layer 140 can be the same. Accordingly, the transfer surface of the donor 100 can be configured as a plane by the surfaces of the plurality of protrusions 132 of the resin layer 130 and the surface of the glass layer 140, but is not limited thereto.

The glass layer 140 can be made of a material having higher rigidity than the resin layer 130, and thus can be referred to as a rigid layer. The glass layer 140 can reinforce the rigidity of the resin layer 130. The glass layer 140 can be configured to support a plurality of protrusions 132 so that the resin layer 130 is not deformed by bonding between the donor 100 and the target substrate during the transfer process. For example, the glass layer 140 can be made of a rigid material such as glass, and can be formed to a thickness of about 30 to 50 μm, but is not limited thereto.

The glass layer 140 can be made of a non-adhesive material. Accordingly, a portion corresponding to the plurality of protrusions of the resin layer 130 in the donor 100 can be defined as an adhesive area ADA to which the plurality of light-emitting elements LED can be temporarily adhered, and a portion corresponding to the glass layer 140 can be defined as a non-adhesive area NADA to which the plurality of light-emitting elements LED are not adhered.

Meanwhile, referring to FIG. 2B, during the transfer process, the plurality of light-emitting elements LED on the wafer or temporary substrate TS can be transferred to the donor 100 and temporarily attached to the upper surface of the protrusion 132 having viscoelasticity.

Thereafter, the plurality of light-emitting elements LED attached to the protrusion 132 of the donor 100 can be transferred to the target substrate.

Referring to FIG. 2B, a single protrusion 132 can be configured to temporarily attach the plurality of light-emitting elements LED. For example, a plurality of light-emitting elements LED1, LED2 and LED3 emitting different colors can be disposed in each of a plurality of unit areas UA on the wafer or the temporary substrate TS. Then, during the transfer process, a unit area UA selected to be transferred from the wafer or the temporary substrate TS to the target substrate using the plurality of protrusions 132 among the plurality of unit areas UA can be referred to as a target area TA. In this case, a single protrusion 132 can be configured to temporarily attach all of the plurality of light-emitting elements LED1, LED2 and LED3 disposed in a single unit area UA selected as the target area TA. At this time, in FIG. 2B, three light-emitting elements LED are depicted as being disposed on one protrusion 132, but the number of light-emitting elements LED disposed on one protrusion 132 can vary depending on the design and is not limited thereto.

Meanwhile, although not illustrated in the drawings, a plurality of alignment protrusions, a plurality of alignment patterns, a plurality of displacement measurement areas, or the like can be further disposed in the inactive area IA. For example, the plurality of alignment protrusions on which an alignment key is transferred and the alignment pattern, which is a mark aligned with an alignment pattern of the temporary substrate or the target substrate, can be formed in the inactive area IA, so that the donor 100 and the temporary substrate or the target substrate can be aligned during the transfer process. In addition, the displacement measurement area, which is an empty space in the inactive area IA where a plurality of dummy protrusions, alignment protrusions, alignment patterns, or the like are not disposed so that a laser can pass through, can be formed, so that the parallelism of the donor 100 can be measured.

Referring to FIG. 2B, the donor 100 can be fixed to a head HD. The head HD is a member that moves the donor 100, and the donor 100 can be fixed to the head HD during the transfer process. For example, an adsorption hole can be formed in the head HD to fix the donor 100 by a vacuum bonding method. The head HD moves the donor 100 to attach the donor 100 to the temporary substrate TS or the target substrate, or to detach the donor 100 from the temporary substrate TS or the target substrate. Accordingly, the head HD can align the donor 100 and the temporary substrate or the target substrate during the transfer process.

Meanwhile, referring to FIG. 2B, the wafer or temporary substrate TS on which the plurality of light-emitting elements LED are disposed can be loaded onto a stage ST. The stage ST is a member that supports the wafer or temporary substrate TS loaded onto the stage ST during the transfer process. The stage ST can support and fix the wafer or temporary substrate TS during the transfer process.

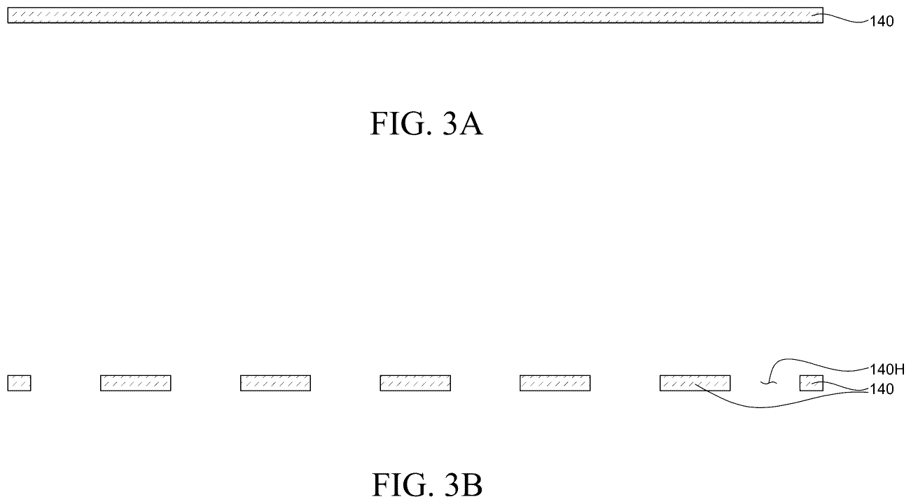

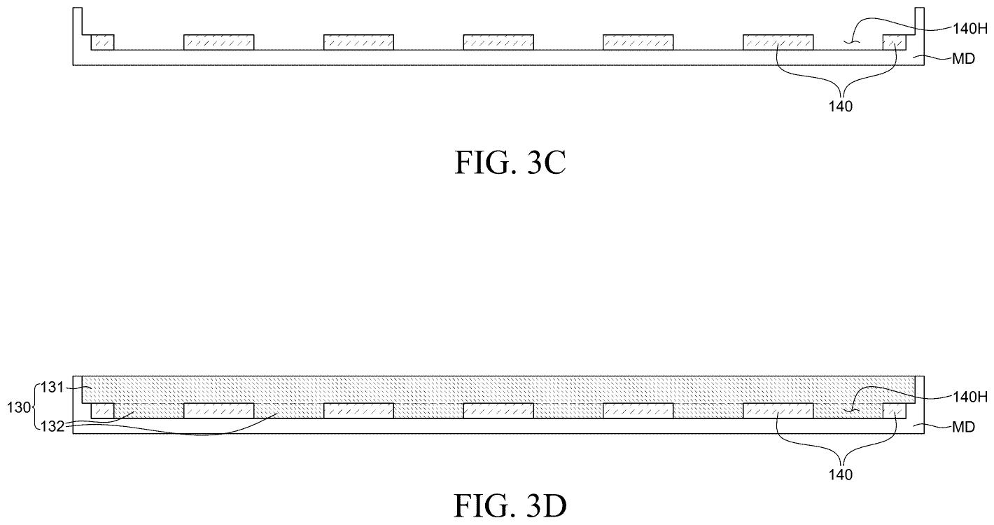

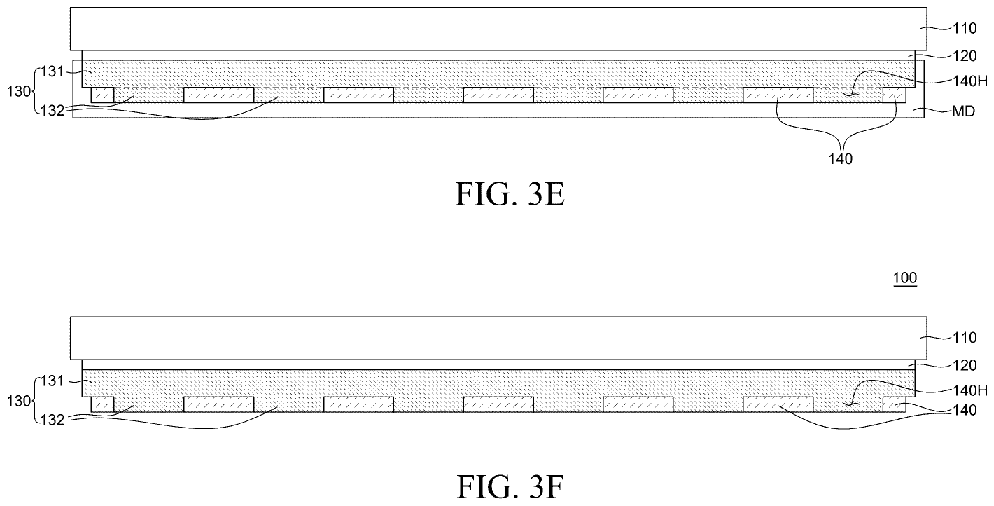

Hereinafter, a manufacturing process of the donor 100 according to one implementation of the present disclosure will be described with reference to FIGS. 3A to 3F.

FIGS. 3A to 3F are cross-sectional views illustrating a manufacturing process of the donor according to one implementation of the present disclosure.

First, referring to FIGS. 3A and 3B, the plurality of holes 140H are formed in the plate-shaped glass layer 140. The method for forming the plurality of holes 140H in the glass layer 140 can be, for example, a method of generating a phase displacement in the glass layer 140 with a laser and then controlling an etching rate to form the holes 140H in a portion where the phase displacement occurs, but is not limited thereto.

Next, referring to FIG. 3C, the glass layer 140 having a plurality of holes 140H formed therein is bonded to a mold MD. The method of bonding the glass layer 140 to the mold MD can be, for example, performed by a process of disposing a material that loses adhesive strength by laser between the glass layer 140 and the mold MD and applying pressure to temporarily bond the glass layer 140 and the mold MD, but is not limited thereto.

Next, referring to FIG. 3D, the resin layer 130 is formed on the upper portion of the glass layer 140 and inside the mold MD. The resin layer 130 can be formed through a process of coating and curing a material for forming the resin layer 130 in the space formed by the glass layer 140 and the mold MD, but is not limited thereto.

Next, referring to FIG. 3E, the substrate 110 is disposed on the resin layer 130 exposed from the mold MD. In this case, the substrate 110 can be bonded to the resin layer 130 through an adhesive layer 120, but is not limited thereto.

Finally, referring to FIG. 3F, the manufacturing process of the donor 100 can be completed by removing the mold MD from the resin layer 130 and the glass layer 140. In this case, the method of removing the mold MD from the resin layer 130 and the glass layer 140 can use, for example, a method of removing the adhesive strength of a material that temporarily adheres the mold MD by irradiating the mold MD with a laser, but is not limited thereto.

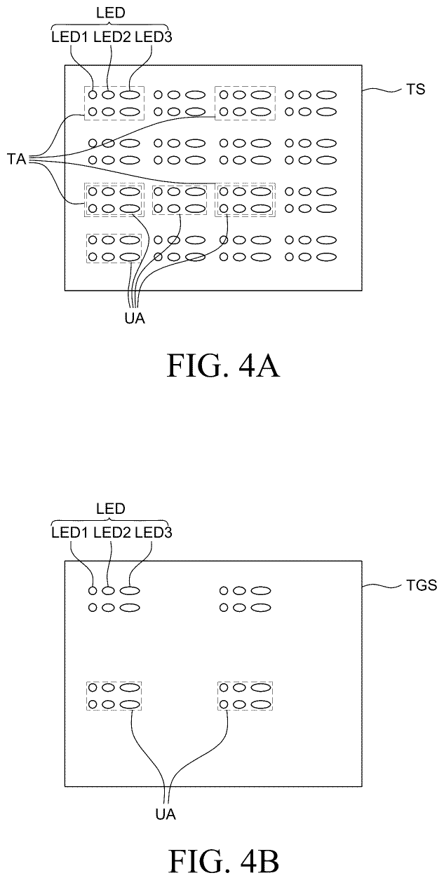

Hereinafter, with reference to FIGS. 4A and 4B, the temporary substrate TS and a target substrate TGS used for transferring the light-emitting elements LED using the donor 100 according to one implementation of the present disclosure will be described.

FIG. 4A is a plan view for explaining a temporary substrate used in a transfer process of the light-emitting element using the donor according to one implementation of the present disclosure. FIG. 4B is a plan view for explaining a state in which the light-emitting element is transferred to the target substrate using the donor according to one implementation of the present disclosure.

In a transfer process using the donor 100, the plurality of light-emitting elements LED on the temporary substrate TS are temporarily attached on the protrusions 132 and transferred to the donor 100, and then the plurality of light-emitting elements LED temporarily attached on the protrusions 132 of the donor 100 can be transferred to the target substrate TGS.

Referring to FIG. 4A, the temporary substrate TS can be a substrate on which the plurality of light-emitting elements LED manufactured from a wafer are disposed in a specific arrangement. The plurality of light-emitting elements LED can be disposed in a specific arrangement on the temporary substrate TS through a self-assembly method or a selective transfer method. The temporary substrate TS can be referred to as an assembly substrate, but is not limited thereto.

For example, a plurality of assembly lines for self-assembling the plurality of light-emitting elements LED can be formed on the temporary substrate TS, and the plurality of light-emitting elements LED can be aligned and self-assembled in a specific arrangement by an electric field formed in the plurality of assembly lines. In this case, the light-emitting elements LED can be dielectrically polarized by the electric field to have polarity, and the dielectrically polarized light-emitting elements LED can be moved or fixed in a specific direction by dielectrophoresis (DEP), that is, the electric field. Accordingly, the plurality of light-emitting elements LED can be self-assembled on the temporary substrate TS in a specific arrangement, for example, at intervals corresponding to a plurality of sub-pixels of the display device, by the plurality of assembly lines. As another example, some of the plurality of light-emitting elements LED on the wafer or another donor 100 can be selectively transferred to the temporary substrate TS, so that the plurality of light-emitting elements LED can be disposed in a specific arrangement on the temporary substrate TS.

A specific arrangement of the plurality of light-emitting elements LED on the temporary substrate TS can be, for example, as illustrated in FIG. 4A, in which the plurality of unit areas UA each including the plurality of light-emitting elements LED are disposed. The plurality of light-emitting elements LED disposed in the plurality of unit areas UA can emit different colors and include a first light-emitting element LED1, a second light-emitting element LED2, and a third light-emitting element LED3 that have different sizes. The plurality of light-emitting elements LED can all have the same size, but are not limited thereto. In this case, an area selected to be transferred to a target substrate TGS among the plurality of unit areas UA disposed on the temporary substrate TS can be defined as the target area TA. That is, a unit area UA selected as the target area TA among the plurality of unit areas UA can be transferred to the target substrate TGS by the donor 100.

Meanwhile, in the transfer process, the wafer can be directly used in addition to the temporary substrate TS. That is, the wafer can be directly disposed on the stage ST in the transfer process. For example, a material such as gallium nitride (GaN) that constitutes the plurality of light-emitting elements LED can be formed on a wafer, a crystal layer can be grown, the crystal layer can be cut into individual chips, and electrodes can be formed to form the plurality of light-emitting elements LED. Then, the wafer on which the plurality of light-emitting elements LED are formed can be directly loaded onto the stage ST to transfer the plurality of light-emitting elements LED on the wafer to the donor 100.

Referring to FIG. 4B, the target substrate TGS can be a substrate used in a final product, such as a display device, to be manufactured using the donor 100. For example, the target substrate TGS can be a member supporting various components of the display device. The plurality of unit areas UA transferred from the donor 100 can be disposed on the target substrate TGS. For example, the plurality of unit areas UA can be configured as a plurality of pixels of the display device, and the plurality of light-emitting elements included in the unit areas UA can be configured as a plurality of sub-pixels, respectively.

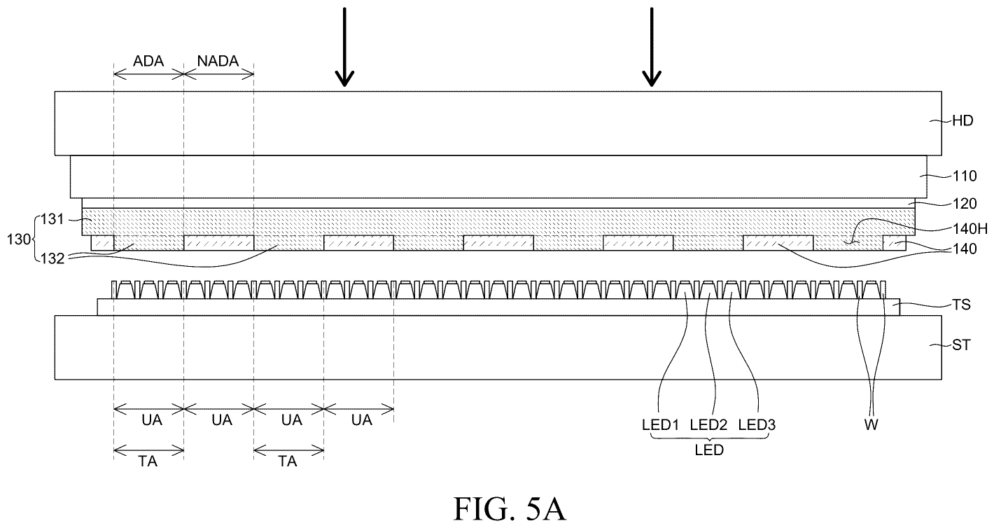

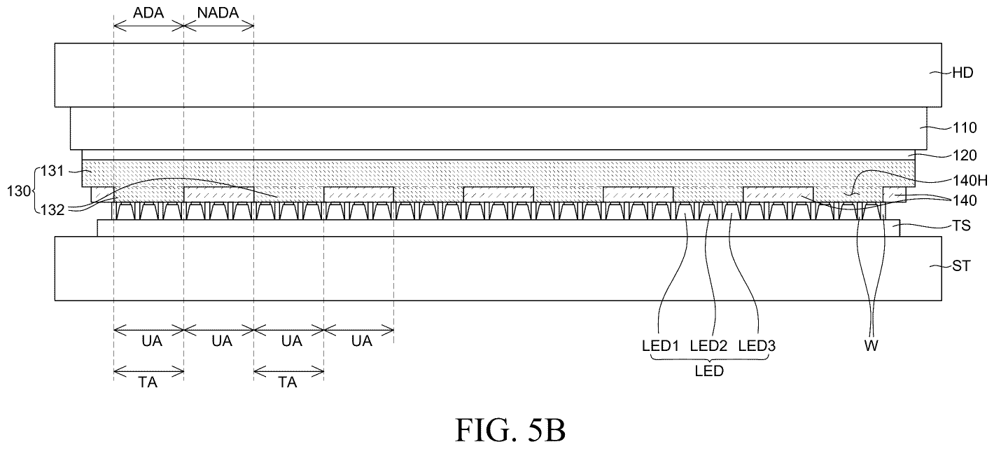

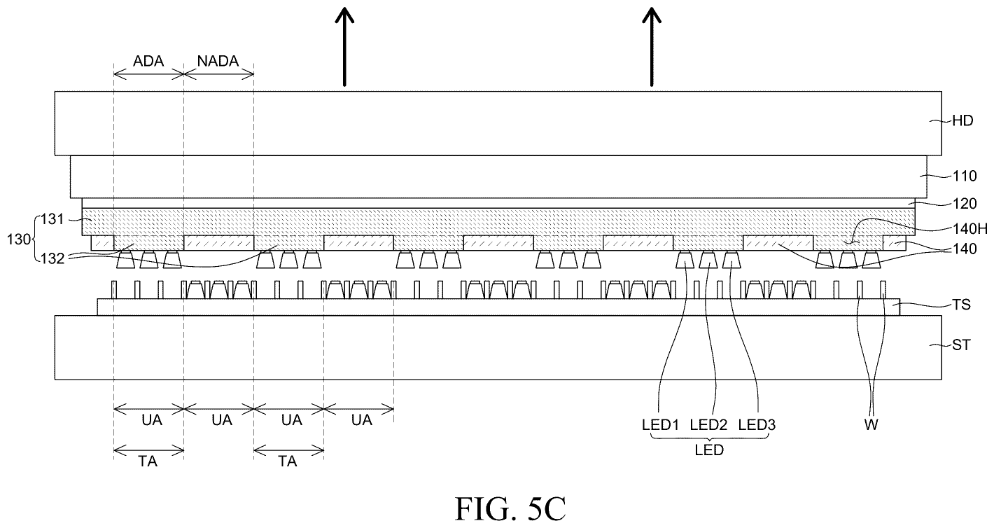

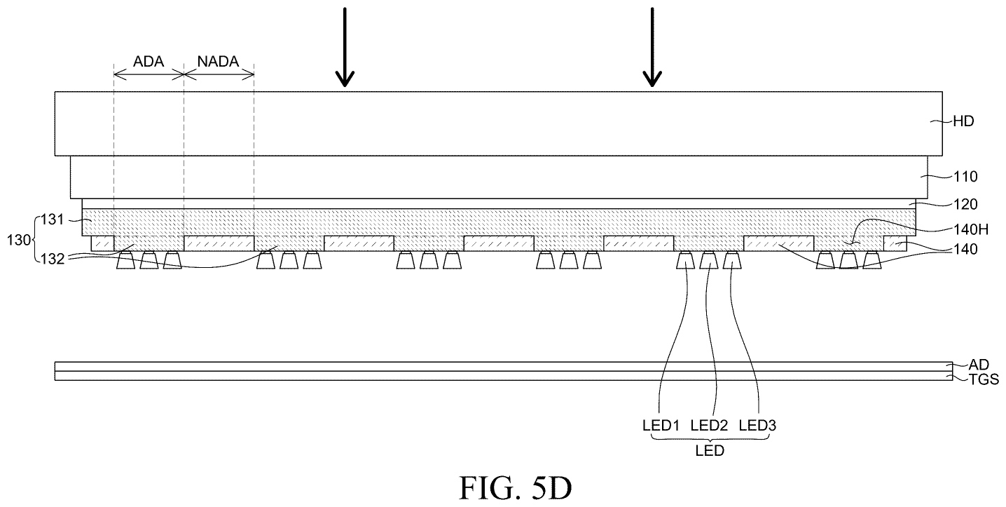

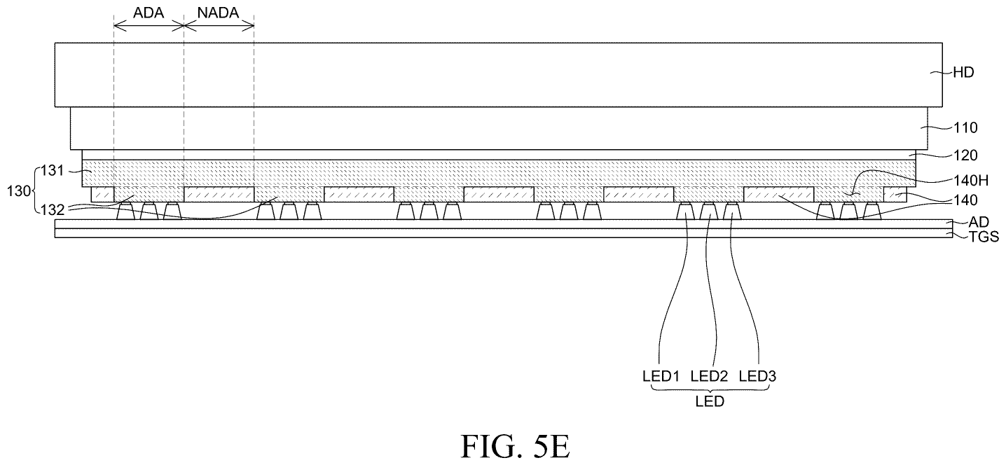

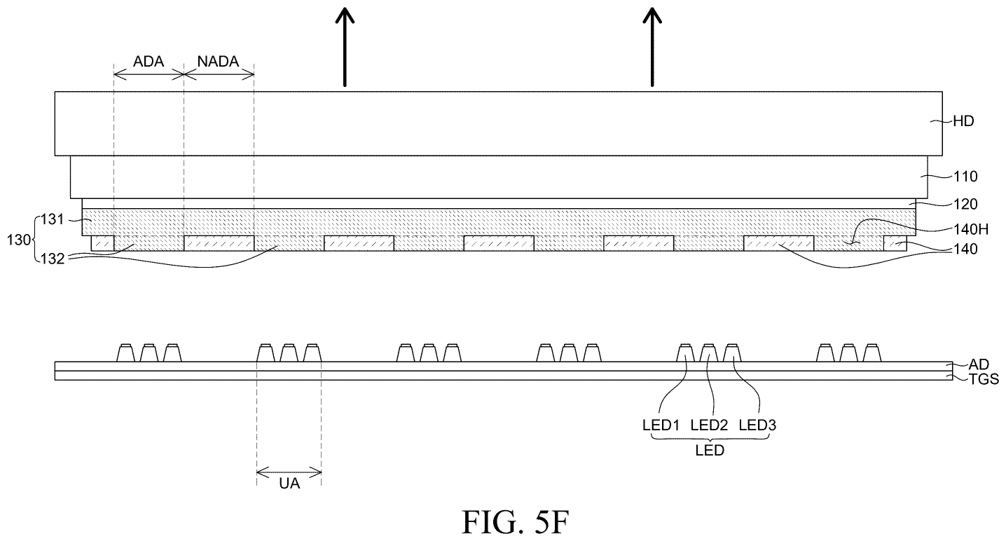

Hereinafter, a method for transferring the light-emitting element LED using the donor 100 according to one implementation of the present disclosure will be described with reference to FIGS. 5A to 5F.

FIGS. 5A to 5F are process diagrams for explaining a method for transferring the light-emitting element using the donor according to one implementation of the present disclosure. Meanwhile, in FIGS. 5A to 5F, the temporary substrate TS is illustrated as being disposed on the stage ST for convenience of explanation. However, the wafer can also be disposed on the stage ST and is not limited thereto.

Referring to FIG. 5A, in order to transfer the plurality of light-emitting elements LED on a temporary substrate TS to the donor 100, the temporary substrate TS is loaded on the stage ST and the donor 100 is fixed to the head HD.

Referring to FIGS. 5A and 5B, the head HD is moved toward the stage ST to bond the temporary substrate TS and the donor 100, and the plurality of light-emitting elements LED on the temporary substrate TS are transferred to the donor 100. In a state where the temporary substrate TS on which the plurality of light-emitting elements LED are disposed is loaded onto the stage ST, the head HD and the donor 100 are moved toward the temporary substrate TS to attach the plurality of light-emitting elements LED to the donor 100. The donor 100 and the temporary substrate TS are bonded so that the plurality of protrusions 132 of the donor 100 are in contact with the plurality of light-emitting elements LED disposed in the unit area UA corresponding to the target area TA, and the plurality of light-emitting elements LED can be transferred from the temporary substrate TS to the donor 100.

In this case, the plurality of light-emitting elements LED corresponding to the glass layer 140 disposed in the non-adhesive area NADA of the donor 100 on the temporary substrate TS can not be transferred to the donor 100 because the plurality of light-emitting elements are in contact with the glass layer 140 that has no adhesive force.

Meanwhile, referring to FIGS. 5A and 5B, a barrier rib W can be disposed between the plurality of light-emitting elements LED of a temporary substrate TS. The barrier rib W can serve to separate the plurality of light-emitting elements LED from each other. For example, the barrier rib W can form an opening having a size corresponding to each light-emitting element on the temporary substrate TS during the process of self-assembling the plurality of light-emitting elements LED having different sizes onto the temporary substrate TS. Accordingly, the barrier rib W can be configured to allow the plurality of light-emitting elements LED emitting different colors to be disposed in a specific arrangement by assembling the plurality of light-emitting elements LED onto a specific position on the temporary substrate TS during the self-assembly process.

Referring to FIG. 5C, the head HD and the donor 100 can be moved upward on the temporary substrate TS to transfer the plurality of light-emitting elements LED from the temporary substrate TS to the donor 100. At this time, the plurality of light-emitting elements LED can be attached to the plurality of protrusions 132 disposed in the adhesive area ADA of the donor 100 and can be separated from the temporary substrate TS.

Referring to FIGS. 5D and 5E, the head HD and the donor 100 are moved toward the target substrate TGS to bond the target substrate TGS and the donor 100, and the plurality of light-emitting elements LED temporarily attached to the donor 100 are transferred to the target substrate TGS. By bonding the donor 100 to which the plurality of light-emitting elements LED are temporarily attached and the target substrate TGS, the plurality of light-emitting elements LED can be transferred from the plurality of protrusions 132 of the donor 100 to the target substrate TGS.

At this time, an adhesive layer AD can be disposed on the target substrate TGS. The adhesive layer AD can adhere the target substrate TGS and the plurality of light-emitting elements LED. The adhesive layer AD can be made of, for example, any one of an adhesive polymer, an epoxy resin, a UV-curable resin, a polyimide series, an acrylate series, a urethane series, and a polydimethylsiloxane (PDMS), but is not limited thereto.

Referring to FIG. 5F, the head HD and the donor 100 can be moved upward on the target substrate TGS to complete the transfer of the plurality of light-emitting elements LED from the donor 100 to the target substrate TGS. In this case, the plurality of light-emitting elements LED temporarily attached to the plurality of protrusions 132 of the donor 100 can be attached to the adhesive layer AD of the target substrate TGS and separated from the plurality of protrusions 132

In this way, by repeating the process of FIGS. 5A to 5F, the plurality of unit areas UA each including the plurality of light-emitting elements LED can be disposed on the target substrate TGS. Accordingly, the donor 100 according to one implementation of the present disclosure can transfer the plurality of light-emitting elements LED so that a plurality of pixels are configured on the target substrate TGS.

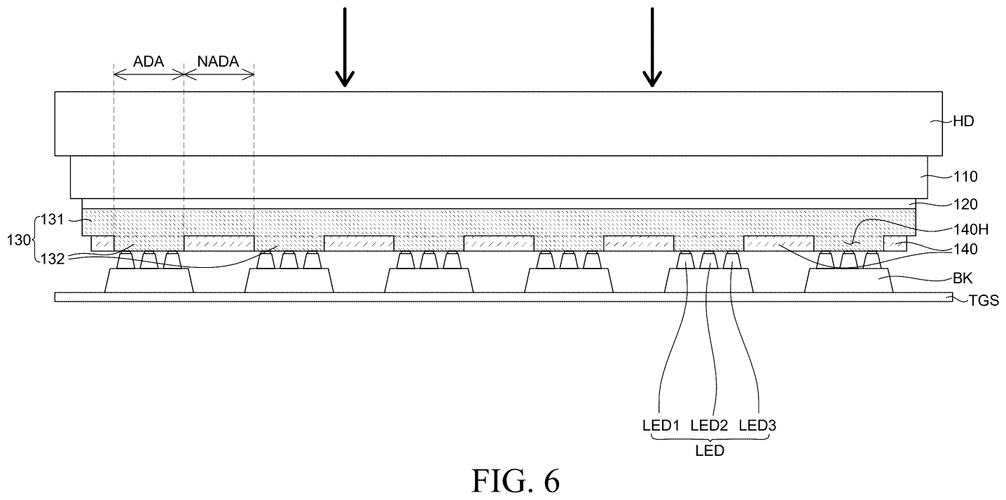

FIG. 6 is a cross-sectional view exemplarily illustrating various target substrates onto which a light-emitting element can be transferred using a donor according to one implementation of the present disclosure.

Meanwhile, referring to FIG. 6, a plurality of banks BK can be disposed on a target substrate TGS. The plurality of banks BK can be structures on which the plurality of light-emitting elements LED are mounted. The plurality of banks BK can guide the positions of the plurality of light-emitting elements LED in the transfer process of transferring the plurality of light-emitting elements LED to the target substrate TGS. In the transfer process of the plurality of light-emitting elements LED, the plurality of light-emitting elements LED can be transferred onto the plurality of banks BK. The plurality of banks BK can be bank patterns or structures, but are not limited thereto. Meanwhile, interference between the donor 100 and the target substrate TGS can be further minimized by the plurality of banks BK, but is not limited thereto.

In the transfer process of the light-emitting element using the donor including the plurality of protrusions having viscoelasticity and adhesiveness, the plurality of protrusions pressed by the bonding of the donor and the temporary substrate or target substrate are deformed, and in addition to the light-emitting element in the target area, light-emitting elements in the peripheral portion can be attached together to the plurality of protrusions. Accordingly, the precision of the transfer using the donor can be reduced, which can cause a problem in that the quality of the final product is also reduced.

Accordingly, the donor 100 according to one implementation of the present disclosure can improve the transfer precision of the donor 100 by disposing the glass layer 140 between the plurality of protrusions 132 of the resin layer 130.

Specifically, the glass layer 140 is disposed between the plurality of protrusions 132 of the resin layer 130. The glass layer 140 includes the plurality of holes 140H, and the plurality of protrusions 132 of the resin layer 130 are accommodated within the plurality of holes 140H of the glass layer 140. In addition, the glass layer 140 can be made of a material having higher rigidity than the resin layer 130. Accordingly, the glass layer 140 can be configured to support the plurality of protrusions 132 so that the resin layer 130 is not deformed by bonding between the donor 100 and the target substrate during the transfer process. Accordingly, the plurality of protrusions 132 can be configured so as not to adhere the light emitting element LED disposed in an area other than the target area TA during the process of temporarily attaching the plurality of light emitting elements LED, thereby improving the transfer precision of the donor 100. Meanwhile, the glass layer 140 can be made of a non-adhesive material. Accordingly, even when the glass layer 140 and the light-emitting element LED disposed in an area other than the target area TA come into contact with each other during the transfer process, the transfer of the light-emitting element LED disposed in an area other than the target area TA to the donor 100 can be minimized due to the non-adhesiveness of the glass layer 140. Accordingly, the transfer precision of the donor 100 can be further improved.

Therefore, the donor 100 according to one implementation of the present disclosure can improve the transfer precision of the donor 100 by disposing the glass layer 140 between the plurality of protrusions 132 of the resin layer 130, and can improve the quality of the final product in which the light-emitting elements LED is transferred using the donor 100.

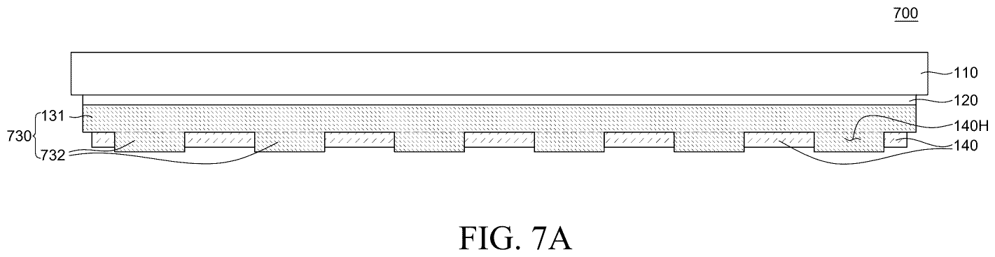

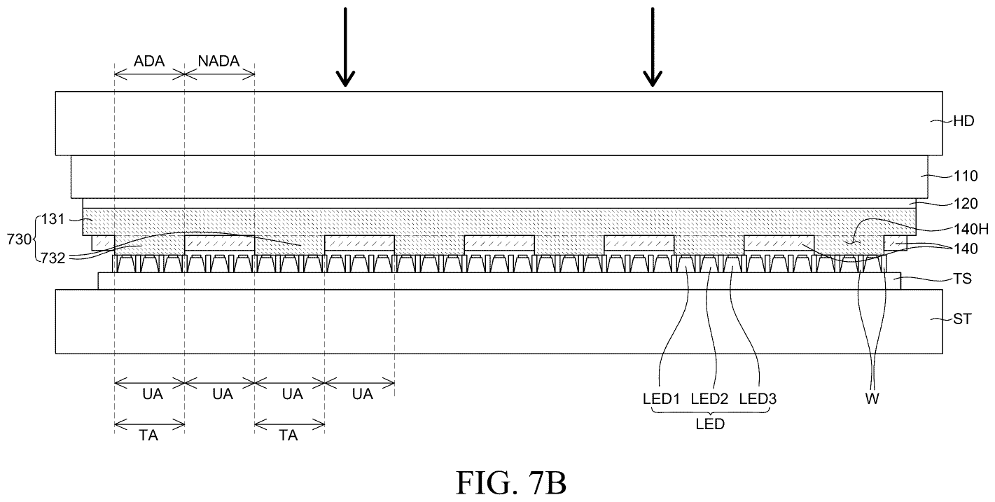

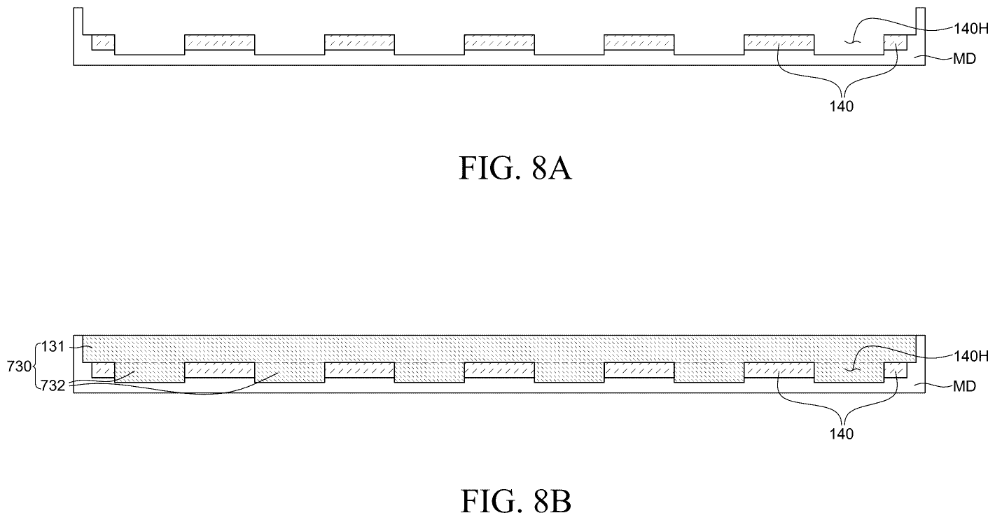

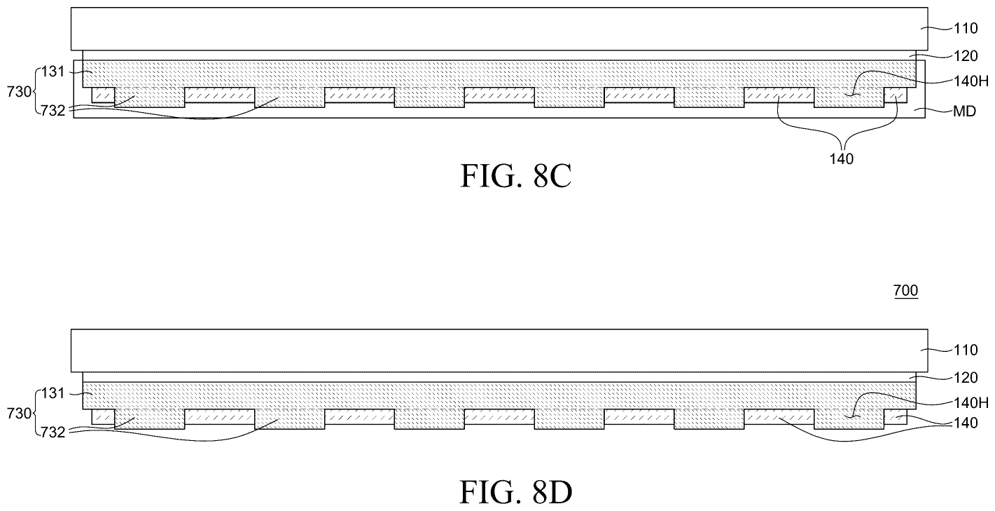

FIG. 7A is a cross-sectional view of a donor according to another implementation of the present disclosure. FIG. 7B is a cross-sectional view illustrating a state in which the donor and a temporary substrate are aligned according to another implementation of the present disclosure. FIGS. 8A to 8D are cross-sectional views for explaining a manufacturing process of the donor according to another implementation of the present disclosure. The donor 700 of FIGS. 7A to 8D is substantially the same as the donor 100 of FIGS. 1 to 6 except that the structure of the plurality of protrusions 732 is different, so that a duplicate description is omitted.

Referring to FIGS. 7A and 7B, the tips of the plurality of protrusions 732 can protrude beyond the surface of the glass layer 140. That is, the plurality of protrusions 732 can be disposed to protrude beyond the surface of the glass layer 140. For example, the plurality of protrusions 732 can be disposed to protrude 10 um from the surface of the glass layer 140, but are not limited thereto.

Hereinafter, with reference to FIGS. 8A to 8D, a manufacturing process of the donor 700 according to another implementation of the present disclosure will be described in detail.

First, referring to FIG. 8A, the glass layer 140 having the plurality of holes 140H formed therein is bonded to the mold MD. At this time, engraved grooves can be disposed in positions corresponding to the plurality of holes 140H of the glass layer 140 in the mold MD. The method of bonding the glass layer 140 to the mold MD can be, for example, performed by a process of disposing a material that loses adhesive strength by laser between the glass layer 140 and the mold MD and applying pressure to temporarily bond the glass layer 140 and the mold MD, but is not limited thereto.

Next, referring to FIG. 8B, a resin layer 730 is formed above the glass layer 140 and inside the mold MD. The resin layer 730 can be formed through a process of coating and curing a material for forming the resin layer 730 in the space formed by the glass layer 140 and the mold MD, but is not limited thereto.

Next, referring to FIG. 8C, the substrate 110 is disposed on the resin layer 730 exposed from the mold MD. In this case, the substrate 110 can be bonded to the resin layer 730 through the adhesive layer 120, but is not limited thereto.

Finally, referring to FIG. 8D, the manufacturing process of the donor 700 can be completed by removing the mold MD from the resin layer 730 and the glass layer 140. In this case, the method of removing the mold MD from the resin layer 730 and the glass layer 140 can use, for example, a method of removing the adhesive strength of a material that temporarily adheres the mold MD by irradiating the mold MD with a laser, but is not limited thereto.

In the donor 700 according to another implementation of the present disclosure, the plurality of protrusions 732 are disposed to protrude from the surface of the glass layer 140, thereby minimizing transfer errors occurring during the transfer process.

Specifically, the plurality of protrusions 732 can protrude from the surface of the glass layer 140. That is, the tips of the plurality of protrusions 732 can protrude beyond the surface of the glass layer 140. Accordingly, the plurality of light-emitting elements LED disposed in a portion corresponding to the non-adhesive area NADA in the transfer process can be configured so that the light-emitting elements LED are not in contact with the glass layer 140. Accordingly, in the process of transferring the light-emitting elements LED from the temporary substrate TS to the donor 700, the contact between the light-emitting elements LED and the glass layer 140 and the transfer of the unselected light-emitting elements LED to the donor 700 are suppressed. Moreover, in the process of transferring the light-emitting elements LED from the donor 700 to the target substrate TGS, it is possible to minimize a reverse transfer problem that the light-emitting elements LED previously transferred to the target substrate TGS are reversely transferred toward the donor 700. Therefore, in the donor 700 according to another implementation of the present disclosure, the plurality of protrusions 732 are disposed to protrude from the surface of the glass layer 140, thereby minimizing transfer errors occurring during the transfer process and improving transfer quality.

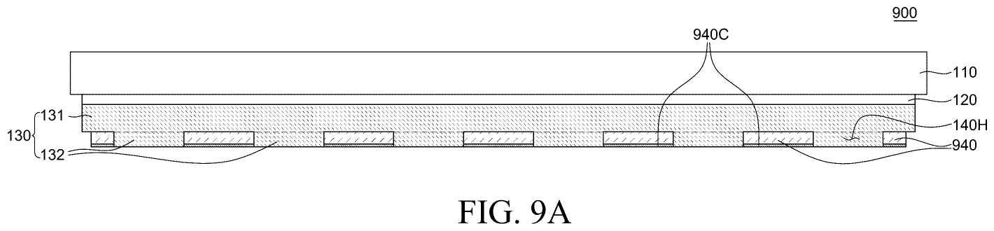

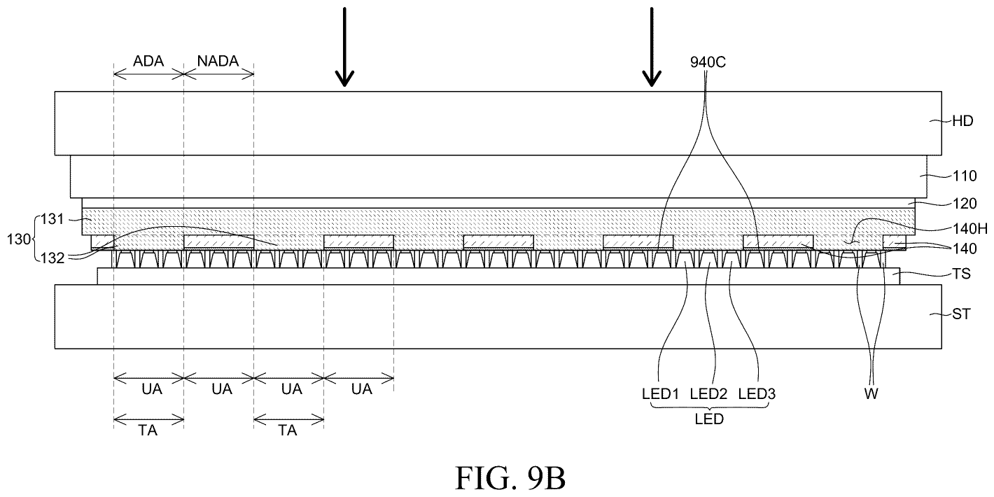

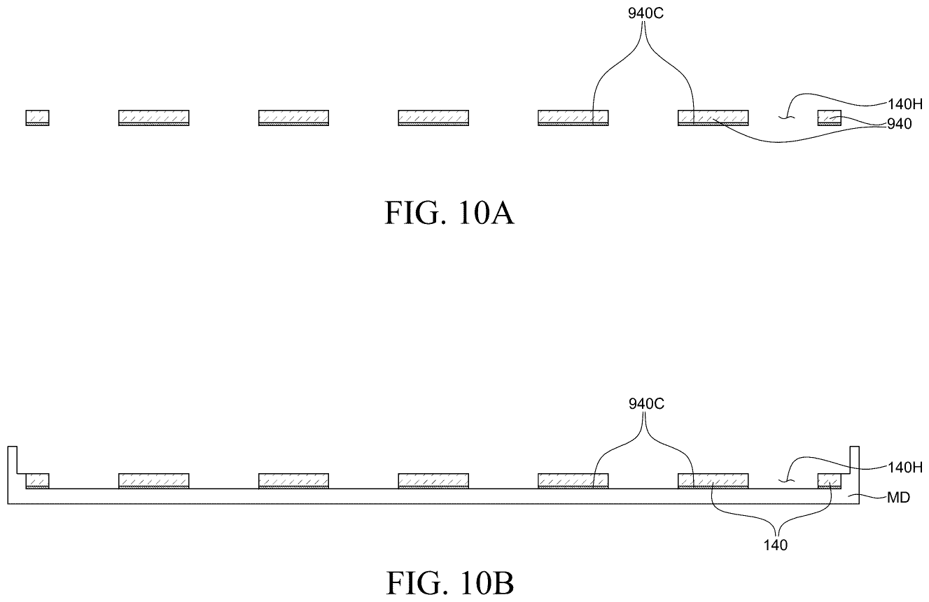

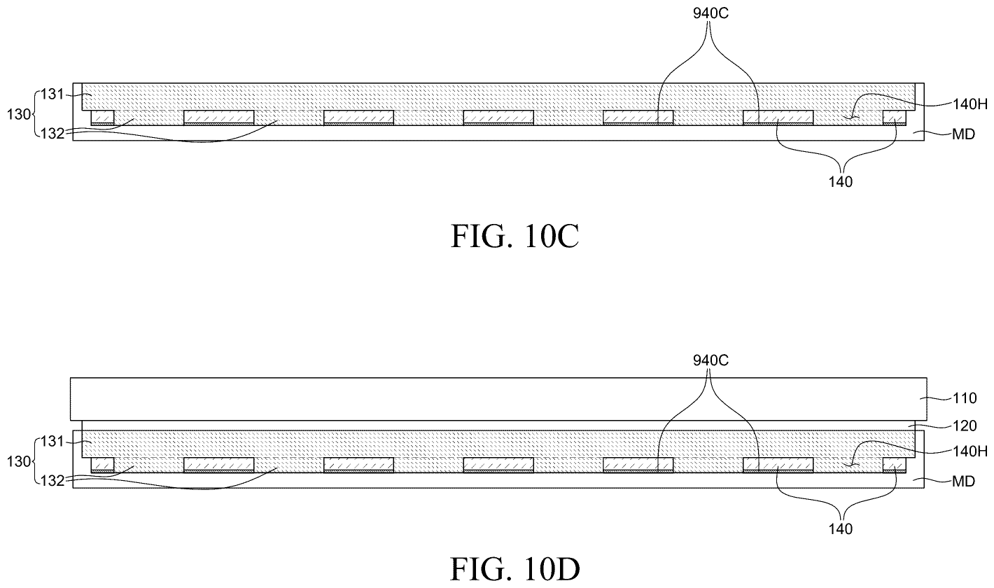

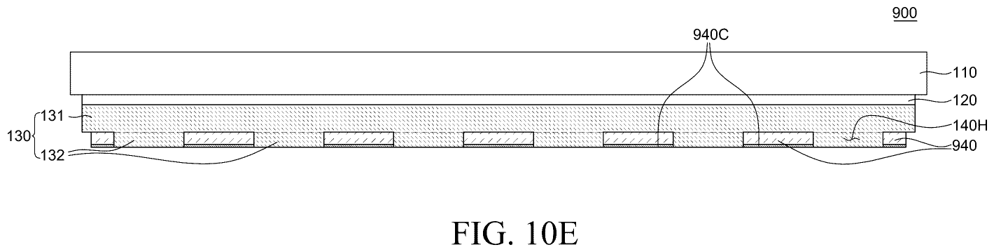

FIG. 9A is a cross-sectional view of a donor according to still another implementation of the present disclosure. FIG. 9B is a cross-sectional view illustrating a state in which the donor and a temporary substrate are aligned according to still another implementation of the present disclosure. FIGS. 10A to 10E are cross-sectional views for explaining a manufacturing process of the donor according to still another implementation of the present disclosure. A donor 900 of

FIGS. 9A to 10E is different from the donor 100 of FIGS. 1 to 6 only in that it further includes a coating layer 940C, and the other configurations are substantially the same, so that a duplicate description is omitted.

Referring to FIGS. 9A and 9B, a glass layer 940 includes the coating layer 940C. The coating layer 940C is disposed on the surface of the glass layer 940. For example, the coating layer 940C can be made of a material including fluorine (F) or silicon (Si), but is not limited thereto.

Hereinafter, with reference to FIGS. 10A to 10E, a manufacturing process of the donor 900 according to still another implementation of the present disclosure will be described in detail.

First, referring to FIG. 10A, the coating layer 940C is formed on one surface of the glass layer 940 on which the plurality of holes 140H are formed. The coating layer 940C can be formed by coating a material including, for example, fluorine (F) or silicon (Si) on one surface of the glass layer 940, but is not limited thereto.

Next, referring to FIG. 10B, one surface of the glass layer 940 on which the coating layer 940C is formed is bonded to the mold MD. The method of bonding the glass layer 940 to the mold MD can be, for example, performed by a process of disposing a material that loses adhesive strength by laser between the glass layer 940 and the mold MD and applying pressure to temporarily bond the glass layer 940 and the mold MD, but is not limited thereto.

Next, referring to FIG. 10C, the resin layer 130 is formed above the glass layer 940 and inside the mold MD. The resin layer 130 can be formed through a process of coating and curing a material for forming the resin layer 130 in a space formed by the glass layer 940 and the mold MD, but is not limited thereto.

Next, referring to FIG. 10D, the substrate 110 is disposed on the resin layer 130 exposed from the mold MD. In this case, the substrate 110 can be bonded to the resin layer 130 through an adhesive layer 120, but is not limited thereto.

Finally, referring to FIG. 10E, the manufacturing process of the donor 900 can be completed by removing the mold MD from the resin layer 130 and the glass layer 940. In this case, the method of removing the mold MD from the resin layer 130 and the glass layer 940 can use, for example, a method of removing the adhesive strength of a material that temporarily adheres the mold MD by irradiating the mold MD with a laser, but is not limited thereto.

In the donor 900 according to still another implementation of the present disclosure, the coating layer 940C is disposed on the surface of the glass layer 940, thereby minimizing transfer errors occurring during the transfer process.

Specifically, the glass layer 940 includes the coating layer 940C, and the coating layer 940C is disposed on the surface of the glass layer 940. The coating layer 940C is a material that has a characteristic of repelling the light-emitting elements LED due to differences in surface properties with the light-emitting elements LED. Accordingly, the plurality of light-emitting elements LED disposed in a portion corresponding to the non-adhesive area NADA in the transfer process can be configured to be in contact with the coating layer 940C and not in contact with the glass layer 140. Accordingly, in the process of transferring the light emitting element LED from the temporary substrate TS to the donor 900, the contact between the light emitting element LED and the glass layer 940 and the transfer of the unselected light emitting element LED to the donor 900 are suppressed. Moreover, in the process of transferring the light emitting element LED from the donor 900 to the target substrate TGS, it is possible to minimize a reverse transfer problem that the light-emitting elements LED previously transferred to the target substrate TGS are reversely transferred toward the donor 900. Accordingly, in the donor 900 according to still another implementation of the present disclosure, since a coating layer 940C is disposed on the surface of the glass layer 940, transfer errors occurring during the transfer process can be minimized, and transfer quality can be improved.

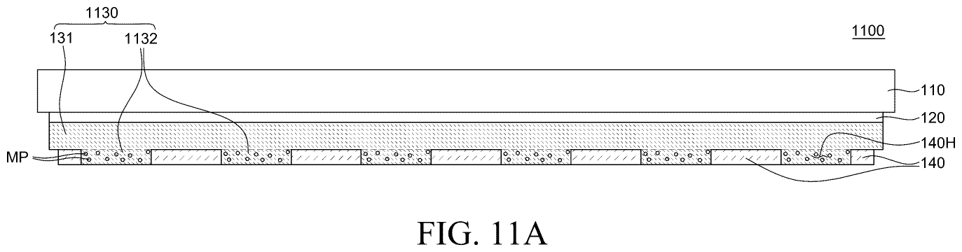

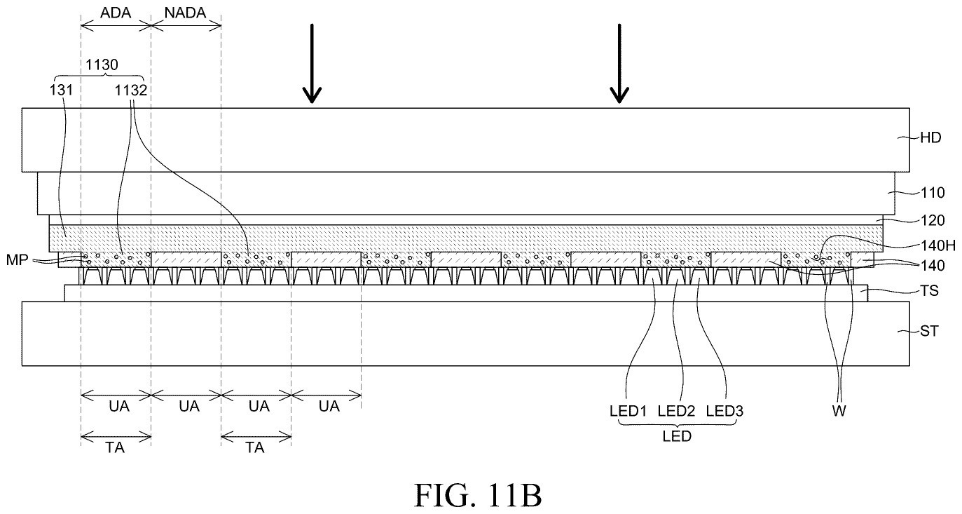

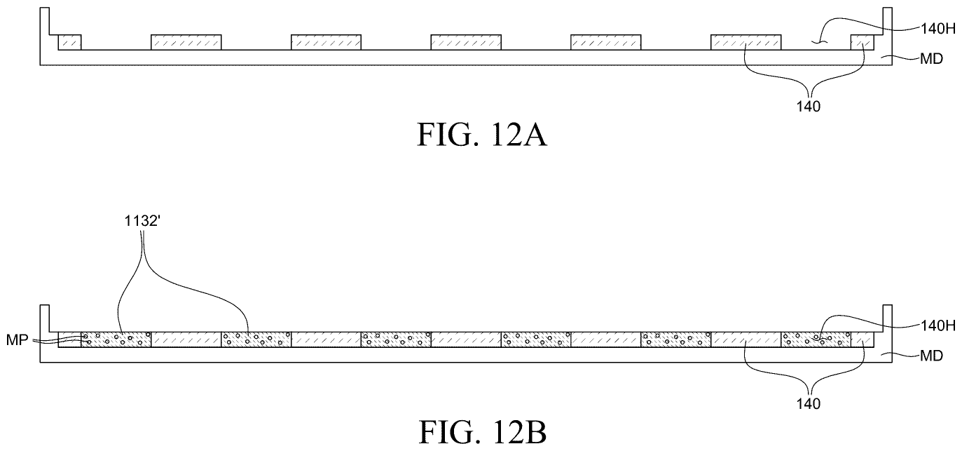

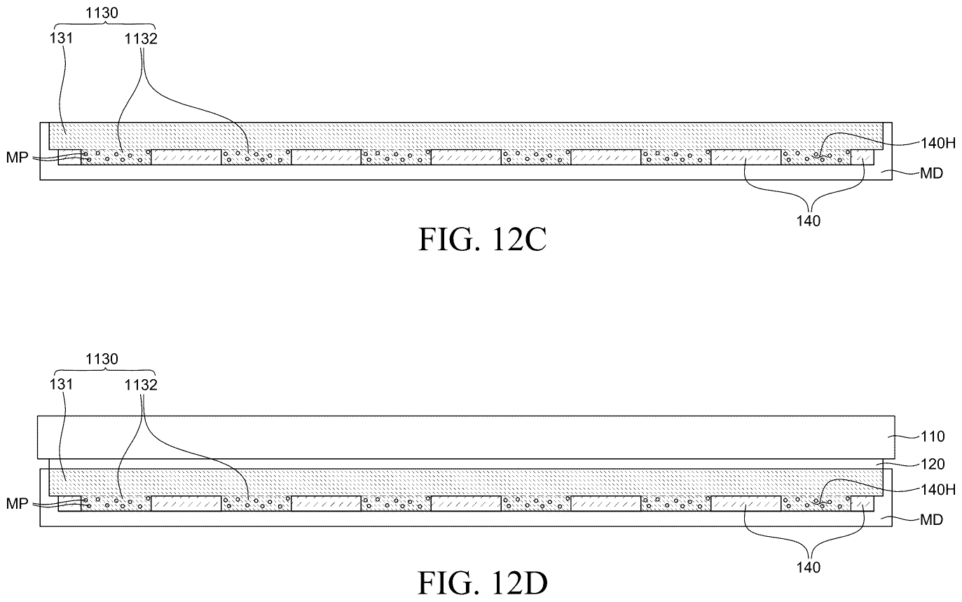

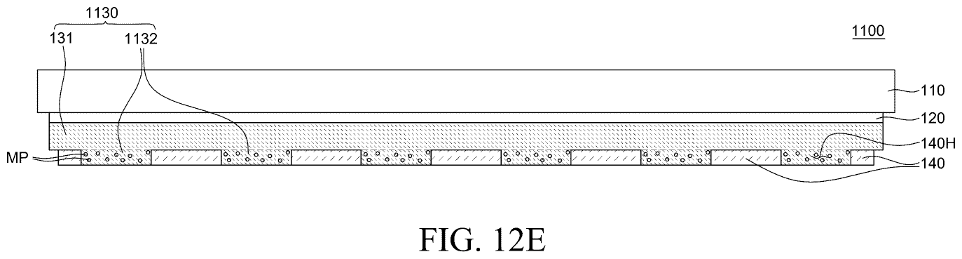

FIG. 11A is a cross-sectional view of a donor according to still another implementation of the present disclosure. FIG. 11B is a cross-sectional view illustrating a state in which the donor and a temporary substrate are aligned according to still another implementation of the present disclosure. FIGS. 12A to 12E are cross-sectional views for explaining a manufacturing process of the donor according to still another implementation of the present disclosure. A donor 1100 of FIGS. 11A to 12E is different from the donor 100 of FIGS. 1 to 6 only in that it further includes a plurality of magnetic particles MP, and the other configurations are substantially the same, so that a duplicate description is omitted.

Referring to FIGS. 11A and 11B, the resin layer 1130 further includes a plurality of magnetic particles MP. The plurality of magnetic particles MP are disposed inside each of the plurality of protrusions 1132 of the resin layer 1130. That is, the plurality of magnetic particles MP are disposed in each of the plurality of protrusions 1132. For example, the magnetic particles MP can be powder of a material having magnetism, such as a magnet, and can have a size of 3 μm or less, but are not limited thereto.

Hereinafter, with reference to FIGS. 12A to 12E, a manufacturing process of the donor 1100 according to still another implementation of the present disclosure will be described in detail.

First, referring to FIG. 12A, the glass layer 140 having the plurality of holes 140H formed therein is bonded to the mold MD. The method of bonding the glass layer 140 to the mold MD can be, for example, performed by a process of disposing a material that loses adhesive strength by laser between the glass layer 140 and the mold MD and applying pressure to temporarily bond the glass layer 140 and the mold MD, but is not limited thereto.

Next, referring to FIG. 12B, the protrusions 1132 including the plurality of magnetic particles MP are formed inside the plurality of holes 140H of the glass layer 140. The resin layer 1130 can be formed through a process of coating and curing a material 1132′ for forming the protrusions 1132 including the plurality of magnetic particles MP in a space formed by the glass layer 140 and the mold MD, but is not limited thereto.

Next, referring to FIG. 12C, the base portion 131 of the resin layer 1130 is formed above the protrusions 1132 including the plurality of magnetic particles MP and inside the mold MD. The base portion 131 can be formed through a process of coating and curing a material for forming the resin layer 1130 in a space formed by the plurality of protrusions 1132 and the mold MD, but is not limited thereto.

Next, referring to FIG. 12D, the substrate 110 is disposed on the resin layer 1130 exposed from the mold MD. In this case, the substrate 110 can be bonded to the resin layer 1130 through an adhesive layer 120, but is not limited thereto.

Finally, referring to FIG. 12E, the manufacturing process of the donor 1100 can be completed by removing the mold MD from the resin layer 1130 and the glass layer 140. In this case, the method of removing the mold MD from the resin layer 1130 and the glass layer 140 can use, for example, a method of removing the adhesive strength of a material that temporarily adheres the mold MD by irradiating the mold MD with a laser, but is not limited thereto.

In the donor 1100 according to still another implementation of the present disclosure, the plurality of magnetic particles MP disposed on each of a plurality of protrusions 1132, thereby minimizing transfer errors occurring during the transfer process.

Specifically, the resin layer 1130 further includes the plurality of magnetic particles MP. The plurality of magnetic particles MP are disposed inside each of the plurality of protrusions 1132 of the resin layer 1130. That is, the plurality of magnetic particles MP having magnetism are disposed in each of the plurality of protrusions 1132. Accordingly, an attractive force can be generated between the light-emitting elements LED and the protrusions 1132 due to the magnetism formed from the plurality of magnetic particles MP, and the problem of the light-emitting elements LED being detached from the plurality of protrusions 1132 during the transfer process can be minimized. Therefore, in the donor 1100 according to still another implementation of the present disclosure, the plurality of magnetic particles MP are disposed in each of the plurality of protrusions 1132, thereby minimizing the problem of the light-emitting elements LED being detached from the plurality of protrusions 1132 during the transfer process, and minimizing transfer errors occurring during the transfer process.

Meanwhile, in the donor 1100 according to still another implementation of the present disclosure, since the plurality of protrusions 1132 having the plurality of magnetic particles MP disposed therein can be supported by the glass layer 140, the movement of the plurality of protrusions 1132 can be restricted. Accordingly, the transfer of the light-emitting elements LED of the non-selected region to the protrusions 1132 having the plurality of magnetic particles MP disposed therein can be minimized.

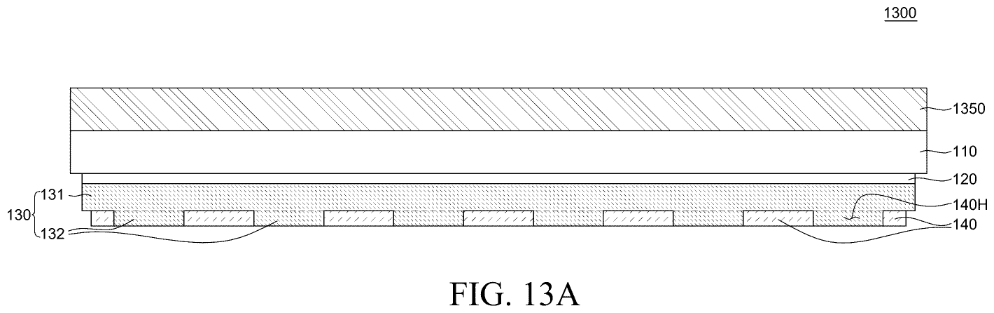

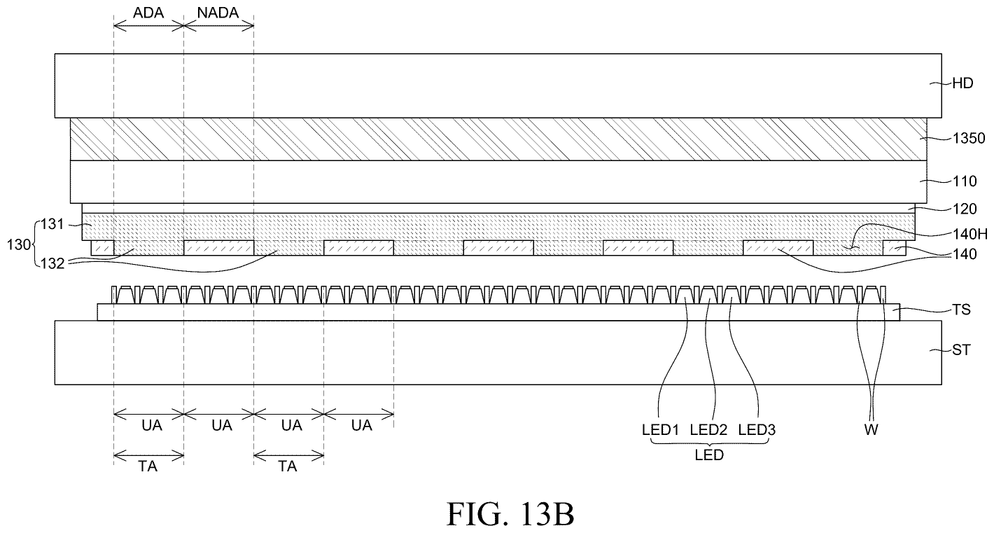

FIG. 13A is a cross-sectional view of a donor according to still another implementation of the present disclosure. FIG. 13B is a cross-sectional view illustrating a state in which the donor and a temporary substrate are aligned according to still another implementation of the present disclosure. A donor 1300 of FIGS. 13A and 13B is different from the donor 100 of FIGS. 1 to 6 only in that an electromagnet plate 1350 is further disposed, and the other configurations are substantially the same, so a duplicate description is omitted.

Referring to FIGS. 13A and 13B, the electromagnet plate 1350 is disposed on the rear surface of the substrate 110. The electromagnet plate 1350 is configured to selectively control a magnetic force. For example, the electromagnet plate 1350 can be controlled to turn the magnetic force on or off by a control unit disposed outside the donor 1300, but is not limited thereto. In this case, the magnetic force of the electromagnet plate 1350 can be, for example, 1000 G or more, but is not limited thereto.

Meanwhile, referring to FIG. 13B, the electromagnet plate 1350 can be configured to be mounted on the head HD in the transfer process. Accordingly, the magnetic force can be configured to be controlled from the control unit through the head HD, but is not limited thereto.

In the donor 1300 according to still another implementation of the present disclosure, the electromagnet plate 1350 is disposed on the rear surface of the substrate 110, so that a bonding force between the light-emitting elements LED and the donor 1300 can be easily controlled during the transfer process.

Specifically, the electromagnet plate 1350 configured to selectively control the magnetic force is disposed on the rear surface of the substrate 110. The electromagnet plate 1350 can be controlled to turn the magnetic force on or off by the control unit disposed on the outside of the donor 1300. Accordingly, the donor 1300 and the temporary substrate TS are bonded to each other so as to be in contact with the plurality of light-emitting elements LED in order to transfer the light-emitting elements LED from the temporary substrate TS to the donor 1300 during the transfer process. Thereafter, the electromagnet plate 1350 is controlled to have a magnetic force so as to enhance the bonding force between the plurality of light-emitting elements LED and the donor 1300. Moreover, in order to transfer the plurality of light-emitting elements LED temporarily attached to the donor 1300 to the target substrate TGS, the donor 1300 to which the plurality of light-emitting elements LED are temporarily attached is bonded to the target substrate TGS. Thereafter, the electromagnet plate 1350 is controlled to lose the magnetic force so that the plurality of light-emitting elements LED can be smoothly separated from the donor 1300. Therefore, in the donor 1300 according to still another implementation of the present disclosure, since the electromagnet plate 1350 is disposed on the rear surface of the substrate 110, the bonding force between the light-emitting elements LED and the donor 1300 can be easily controlled during the transfer process, and the transfer process using the donor 1300 can be conveniently provided.

Meanwhile, although not illustrated in FIGS. 13A and 13B, the resin layer can further include a plurality of magnetic particles. In this case, the plurality of magnetic particles can be disposed inside each of the plurality of protrusions of the resin layer. By disposing the plurality of magnetic particles inside each of the plurality of protrusions, the electromagnet plate disposed on the rear surface of the substrate can be configured to more easily control the bonding force between the light-emitting element and the donor during the transfer process. Accordingly, the plurality of magnetic particles can be disposed inside each of the plurality of protrusions of the resin layer to help the magnetic force of the electromagnet plate act more effectively on the light-emitting element.

The example implementations of the present disclosure can also be described as follows:

According to an aspect of the present disclosure, a donor according to one implementation of the present disclosure includes: a substrate; a resin layer disposed on the substrate and including a base portion and a plurality of protrusions; and a glass layer disposed between the plurality of protrusions on the resin layer.

The glass layer can fill all portions between the plurality of protrusions on the base portion.

The plurality of protrusions can be disposed in a matrix shape, and the glass layer can be a mesh shape disposed to correspond to areas between the plurality of protrusions.

Tips of the plurality of protrusions and a surface of the glass layer can be disposed on the same plane.

Tips of the plurality of protrusions can protrude beyond a surface of the glass layer.

The donor can further comprise a coating layer disposed on a surface of the glass layer.

The coating layer can contain fluorine (F) or silicon (Si).

The resin layer can further include a plurality of magnetic particles disposed inside each of the plurality of protrusions.

The donor can further comprise an electromagnet plate disposed on a rear surface of the substrate and configured to selectively control a magnetic force.

According to another aspect of the present disclosure, a donor according to one implementation of the present disclosure includes: a substrate made of a material having rigidity; a resin layer disposed on the substrate and including a base portion and a plurality of protrusions; and a rigid layer disposed on the resin layer and having a plurality of holes disposed to accommodate the plurality of protrusions.

The rigid layer can be disposed so as to be in contact with the base portion between the plurality of protrusions.

The base portion and the plurality of protrusions can be formed integrally.

The rigid layer can have higher rigidity than the resin layer.

Tips of the plurality of protrusions can be disposed on the same plane as a surface of the rigid layer.

Tips of the plurality of protrusions can protrude beyond a surface of the rigid layer.

The rigid layer can further include a coating layer disposed on a surface of the rigid layer and containing fluorine (F) or silicon (Si).

A plurality of magnetic particles can be disposed in each of the plurality of protrusions.

The donor can further comprise an electromagnet plate disposed on a rear surface of the substrate and capable of controlling a magnetic force to turn on or off.

Although the example implementations of the present disclosure have been described in detail with reference to the accompanying drawings, the present disclosure is not limited thereto and can be implemented in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A donor comprising:
a substrate;
a resin layer disposed on the substrate and including a base portion and a plurality of protrusions; and
a glass layer disposed between the plurality of protrusions on the resin layer.

2. The donor according to claim 1, wherein the glass layer fills all portions between the plurality of protrusions on the base portion.

3. The donor according to claim 1, wherein the plurality of protrusions are disposed in a matrix shape, and
the glass layer is a mesh shape disposed to correspond to areas between the plurality of protrusions.

4. The donor according to claim 1, wherein tips of the plurality of protrusions and a surface of the glass layer are disposed on the same plane.

5. The donor according to claim 1, wherein tips of the plurality of protrusions protrude beyond a surface of the glass layer.

6. The donor according to claim 1, further comprising a coating layer disposed on a surface of the glass layer,
wherein the coating layer contains fluorine (F) or silicon (Si).

7. The donor according to claim 1, wherein the resin layer further includes a plurality of magnetic particles disposed inside each of the plurality of protrusions.

8. The donor according to claim 1, further comprising an electromagnet plate disposed on a rear surface of the substrate and configured to selectively control a magnetic force.

9. A donor comprising:
a substrate made of a material having rigidity;
a resin layer disposed on the substrate and including a base portion and a plurality of protrusions; and
a rigid layer disposed on the resin layer and having a plurality of holes disposed to accommodate the plurality of protrusions.

10. The donor according to claim 9, wherein the rigid layer is disposed so as to be in contact with the base portion between the plurality of protrusions.

11. The donor according to claim 9, wherein the base portion and the plurality of protrusions are formed integrally.

12. The donor according to claim 9, wherein the rigid layer has higher rigidity than the resin layer.

13. The donor according to claim 9, wherein tips of the plurality of protrusions are disposed on the same plane as a surface of the rigid layer.

14. The donor according to claim 9, wherein tips of the plurality of protrusions protrude beyond a surface of the rigid layer.

15. The donor according to claim 9, wherein the rigid layer further includes a coating layer disposed on a surface of the rigid layer and containing fluorine (F) or silicon (Si).

16. The donor according to claim 9, wherein a plurality of magnetic particles are disposed in each of the plurality of protrusions.

17. The donor according to claim 9, further comprising an electromagnet plate disposed on a rear surface of the substrate and capable of controlling a magnetic force to turn on or off.
